(19) United States
(12) Patent Application Publication
(10) Pub. No.: US 2004/0040509 A1
(43) Pub. Date: Mar. 4, 2004

(54) Apparatus and method for preventing etchant condensation on wafer in a cooling chamber

(75) Inventors: Kuo-Liang Lu, Hsin-Chu (TW); Chin-Yuan Hsu, Hsin-Chu (TW); Wen-Zhong Ho, Hsin-Chu (TW); Chong-Lee Chen, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/235,120

(22) Filed: Sep. 4, 2002

(51) Int. Cl. H01L 21/306

(52) U.S. Cl. 118/724; 156/345.53

(57) ABSTRACT

An apparatus and a method for preventing etchant condensation on a wafer surface positioned in a wafer cool-down chamber after plasma etching. The apparatus of the process chamber includes a chamber enclosure of elongated shape with an aperture in a top plate, a heating means mounted on the top plate for heating a wafer through the aperture positioned in the cavity; and an exhaust means in fluid communication with an exhaust opening provided at a back end of the chamber enclosure for evacuating gaseous content in the cavity during and after the heating of the wafer, and for cooling the wafer after the radiant heater is turned off.

### FIELD OF THE INVENTION

The present invention generally relates to a semiconductor processing apparatus and method, more particularly, relates to a semiconductor wafer cooling chamber equipped with a heating device for preventing etchant condensation on the wafer and a method for cooling a wafer.

### BACKGROUND OF THE INVENTION

In the fabrication of modern integrated circuit devices, one of the key elements is to construct plugs or interconnects in reduced dimensions for use in multi-level metallization structures. The numerous processing steps involved require the formation of via holes for the plug or interconnect in a dimension of 0.5 μm or less for high-density logic devices. For instance, in forming tungsten plugs by a chemical vapor deposition method, via holes in such small dimensions must be formed by etching through layers of oxide and spin-on-glass materials at a high etch rate. A high-density plasma etching process utilizing various fluorine or bromine chemistry is used for the via formation process.

During a plasma etching process, etchant gas molecules are first disintegrated by the plasma producing highly reactive components of the etchant gas. The plasma further charges the ions and make them carry positive electricity. On the other hand, the wafer is positioned on an electro-static chuck and charged with a negative bias voltage. When the positively charged plasma ions are attracted by the negatively charged wafer, the plasma ions accelerate toward the negatively charged wafer and bombard the wafer vertically on the wafer surface. Highly efficient etching of the wafer surface is thus achieved.

In modern semiconductor processing, cluster-type equipment is frequently used for the etching or deposition of wafers. The cluster-type tools are popular since it can be efficient in space utilization, i.e. only a smaller space is required in the cleanroom and when the various process chambers such as loadlock chambers, orientation chambers, pre-clean chambers, cool-down chambers and PVD or CVD chambers are grouped together, the semiconductor process can be carried out efficiently with minimum contamination and achieving maximum throughput.

After a semiconductor wafer is processed in a plasma etch chamber, and before the wafer is either restored in a wafer storage cassette or moved into the next process chamber, the wafer must be cooled to a reasonably low temperature. For instance, during a plasma etching process, the wafer surface may be heated to over 200° C. and therefore, must be cooled down to 70° C. or below in order to be moved to the next process station or to be stored.

A typical cool-down chamber 10 is shown in FIG. 1, while a perspective view of the various components of the cool-down chamber 10 is shown in FIG. 1A. The cool-down chamber 10 is constructed of a chamber enclosure 12 having a top plate 14 thereon. The chamber enclosure 12 has a front end defined by a cover plate 16 and a front opening 18. The front opening 18 allows the loading or unloading of wafer 20 into/out of the cavity 22 of the chamber enclosure 12. The wafer 20 is positioned on support 24 placed inside the cavity 22. At the back end of the chamber enclosure 12, an exhaust opening 26 is provided for connecting to an exhaust means, such as a factory exhaust line.

In a conventional cool-down process for a wafer that was dry etched in a plasma etching process, the wafer is positioned in the cool-down chamber 10 for approximately 20 sec., while simultaneously, any residual etchant gas left on the surface of the wafer may be evacuated by the exhaust opening 26 into a factory exhaust line. For instance, in one of the plasma etching process, hydrogen bromide (HBr) may be left on the surface of the wafer when the wafer is moved into the cool-down chamber. When the temperature of the wafer suddenly drops due to the cooling effect of air evacuated from the cool-down chamber, hydrogen bromide gas condenses onto the surface of the wafer and thus, causing serious particle contamination problem. Similarly, other etchant gas residue on the wafer surface may also condense into particulate contaminants during a wafer cool-down process conducted in the cool-down chamber. In order to reduce or eliminate the condensation of residual etchant gas on wafer surface and thus, leading to particulate contamination problem, a solution is to conduct a hard bake process to evaporate the etchant gas residue from the wafer surface. The hard bake process is conducted prior to the after etch inspection (AEI)step. The hard bake necessitates requires an additional process step and occupies another furnace. The throughput of the fabrication process also suffers due to the extra time required for hard bake.

It is therefore an object of the present invention to provide an apparatus and a method for preventing etchant condensation on wafers in a cooling chamber.

It is another object of the present invention to provide an apparatus for cooling-down a wafer that does not cause etchant condensation on the wafer surface.

It is a further object of the present invention to provide an apparatus for preventing etchant condensation on wafer in a cool-down chamber by utilizing a heating device at the beginning of the cool-down process.

It is another further object of the present invention to provide a process chamber for cooling a wafer incorporating a heating device and an evacuation means for removing gaseous content in the cavity of the process chamber.

It is still another object of the present invention to provide a process chamber for cooling a wafer that is equipped with a radiant heating device such that the wafer surface can be rapidly heated to prevent condensation of etchant gas.

It is yet another object of the present invention to provide a process chamber for cooling a wafer incorporating a heating device of a quartz lamp for rapidly heating the wafer surface during evacuation of the cooling chamber to prevent condensation of the etchant gas.

It is still another further object of the present invention to provide a method for cooling a wafer in a cool-down chamber without particulate contamination problem caused by the condensation of residual etchant gas on the wafer surface.

### SUMMARY OF THE INVENTION

In accordance with the present invention, an apparatus and a method for preventing etchant condensation on wafer in a cooling chamber are provided.

In a preferred embodiment, a process chamber for cooling a wafer is provided which includes a chamber enclosure of elongated shape that has a front end, a back end, and a top plate, the front end is equipped with an opening for loading/unloading a wafer into/out of a cavity in the chamber enclosure, the back end is equipped with an exhaust opening, while the top plate is equipped with an aperture; a heating device mounted on the top plate for heating through the aperture a wafer positioned in the cavity; and an exhaust means in fluid communication with the exhaust opening in the chamber enclosure for evacuating gaseous content in the cavity and for cooling the wafer.

In the process chamber for cooling a wafer, the heating device may include a radiant heating device, or a heating lamp, or a quartz lamp. The heating device may further include a plurality of heating lamps. The exhaust means may include a factory exhaust line, capable of exhausting gaseous content of the cavity at a flow rate between about 1 CFM and about 50 CFM. The cavity in the chamber enclosure may further include a support plate equipped with slots for positioning a plurality of wafers.

The present invention is further directed to a method for cooling a wafer in a cool-down chamber without particulate contamination which can be carried out by the operating steps of first providing a chamber enclosure of elongated shape that has a front end, a back end, and a top plate, the front end is equipped with an opening for loading/unloading a wafer into/out of a cavity in the chamber enclosure, the back end is equipped with an exhaust opening in fluid communication with an exhaust means, the top plate is equipped with an aperture and a heating device mounted on the aperture; heating a wafer positioned in the cavity to a temperature of at least 100° C. for a time period of at least 5 sec.; evacuating, simultaneously with the heating step, a gaseous content in the cavity; and evacuating, after termination of the heating step, a gaseous content in the cavity for at least 5 sec.

The method for cooling a wafer in a cool-down chamber without particulate contamination may further include the step of mounting a radiant heating device on the aperture of the top plate of the chamber enclosure, or the step of mounting a heating lamp on the aperture of the top plate of the chamber enclosure, or the step of mounting a plurality of radiant heating means on the aperture of the top plate of the chamber enclosure.

The method may further include the step of heating the wafer positioned in the cavity for a time period between about 5 sec. and about 30 sec., and preferably for a time period between about 10 sec. and about 20 sec. The method may further include the step of evacuating, simultaneous with and after termination of the heating step, a gaseous content in the cavity for a total time period between about 10 sec. and about 50 sec. The method may further include the step of evacuating, simultaneous with and after termination of the heating step, a gaseous content in the cavity at a flow rate of at least 1 CFM. The method may further include the step of heating the wafer positioned in the cavity to a temperature of at least 150° C. for a time period of at least 5 sec. The method may further include the step of evacuating, after termination of the heating step, a gaseous content in the cavity until a temperature of the wafer drops to not higher than 70° C.

### BRIEF DESCRIPTION OF THE DRAWINGS

These and other objects, features and advantages of the present invention will become apparent from the following detailed description and the appended drawings in which:

FIG. 1 is a perspective view of a conventional cool-down chamber for semiconductor wafers.

FIG. 1A is a perspective view of the components in the conventional cool-down chamber of FIG. 1.

FIG. 2 is a perspective view of the present invention cool-down chamber equipped with a heating device.

FIG. 2A is a cross-sectional view of the present invention cool-down chamber of FIG. 2.

FIG. 3 is a graph illustrating the dependency of the wafer temperature on the heating time period at various heating efficiency of the quart lamp.

FIG. 4 is a process flow chart of the present invention method for cooling down a wafer.

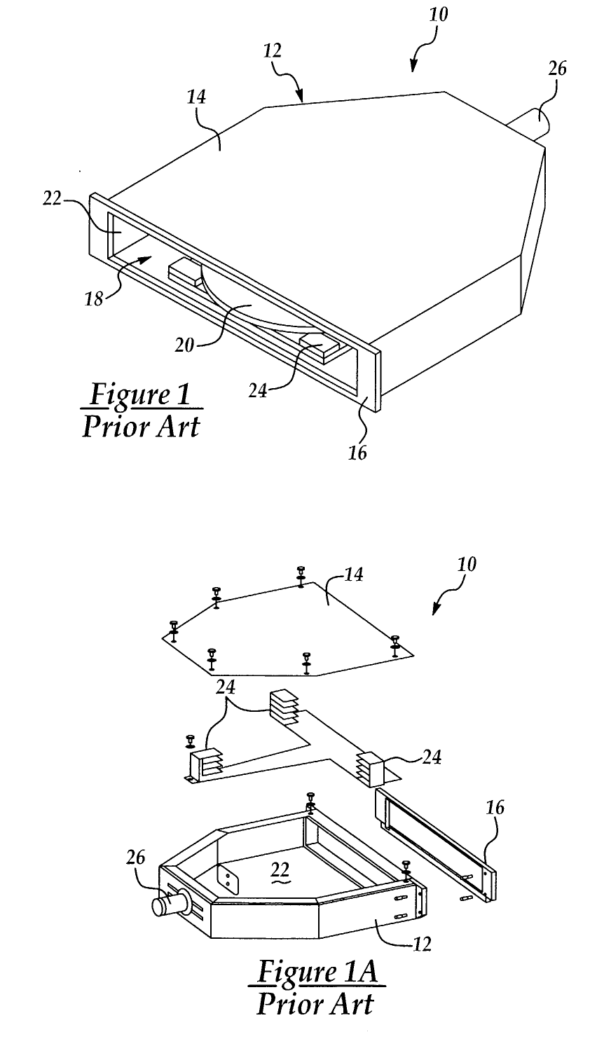

### DETAILED DESCRIPTION OF THE PREFERRED EMBODIMENT

The present invention discloses an apparatus and a method for preventing etchant gas condensation on wafer in a cooling chamber.

In the apparatus, a process chamber for cooling a wafer is constructed by a chamber enclosure of elongated shape, a heating device mounted on top of the chamber enclosure and in communication with the chamber cavity through an aperture, and an exhaust means for evacuating the chamber cavity. The chamber enclosure is frequently fabricated of stainless steel and has an elongated shape with a front end and a back end. The front end is provided with an opening for loading/unloading a wafer into/out of the cavity of the chamber enclosure. The back end is provided with an exhaust opening, or an exhaust conduit for fluid communication with an exhaust means, such as a factory exhaust line. A suitable rate of evacuation, i.e. a suitable flow rate of the gaseous content of the cavity is between about 1 CFM and about 50 CFM, a frequently used flow rate is between about 5 CFM and about 10 CFM. A planar top plate of the chamber enclosure is further provided with an aperture to allow radiant heat to penetrate into the chamber cavity and onto a top surface of a wafer. The heating device mounted on the top planar plate of the chamber enclosure provides radiant heat through the aperture onto the top surface of the wafer and thus, heating the wafer to a temperature of at least 100° C., and preferably at least 150° C. At such high temperature, any condensation of residual etchant gas onto the wafer surface can be prevented. The exhaust means in fluid communication with the exhaust opening in the chamber enclosure may be a factory exhaust line which provides a suitable air flow, or a gaseous flow through the factory exhaust line for evacuating the gaseous content in the cavity and, simultaneously cooling the wafer surface.

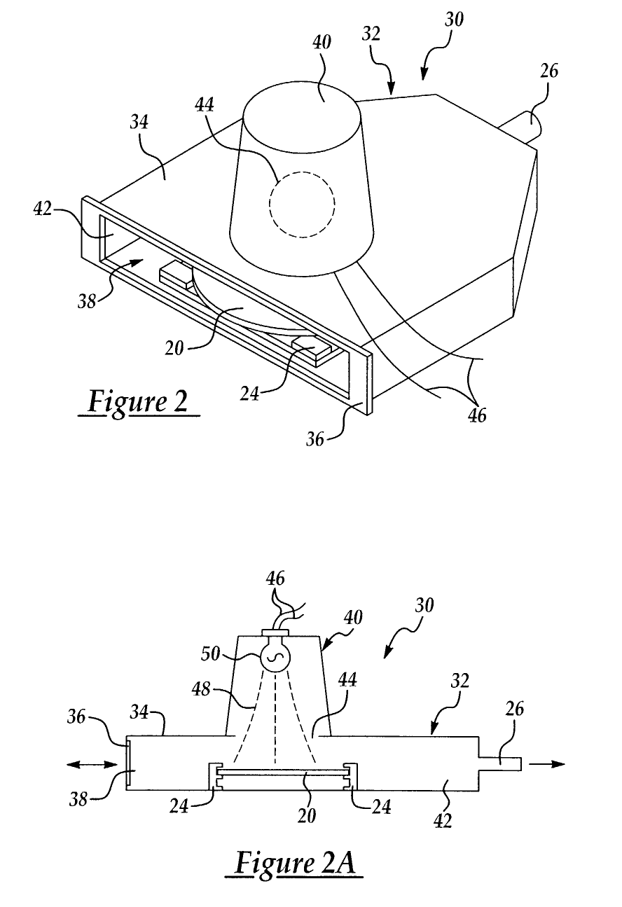

Referring now to FIG. 2, wherein a present invention wafer cool-down chamber 30 is shown. The cool-down chamber 30 is constructed of a chamber enclosure 32 which has a front end defined by a plate 36 and a front opening 38. An exhaust opening 26 is provided at a back end of the chamber enclosure 32. A wafer 20 is positioned on wafer support 24 inside the cavity 42. The top plate 34 is provided an aperture 44 for communicating with a heating device 40. The heating device 40, i.e., as a heating lamp or any other radiant heating means, is powered by power supply 46.

A cross-sectional view of the present invention cool-down chamber 30 is shown in FIG. 2A. As shown in FIG. 2A, the radiant heat 48 penetrates through the aperture 44 in the top plate 34 and is received by the top surface of wafer 20. When a radiant heating means is used, a temperature of at least 100° C. on the wafer surface can be achieved. Frequently, a temperature of higher than 150° C. can be achieved. The radiant heating device may be a heating lamp, such as a quartz lamp 50 shown in FIG. 2A.

It should be noted that the heating device may also employ a plurality of heating lamps to achieve more uniform heating of the wafer surface. A larger aperture 44 may be required to allow for heat penetration through the aperture onto the wafer surface from a plurality of heating sources.

The exhaust means that is in fluid communication, by connecting to the exhaust opening 26, may be advantageously a factory exhaust line which provides a flow rate for the gaseous content of the cavity between about 1 CFM and about 50 CFM, or preferably between about 5 CFM and between about 10 CFM. Other exhaust means such as an air pump may also be utilized to achieve the same desirable result.

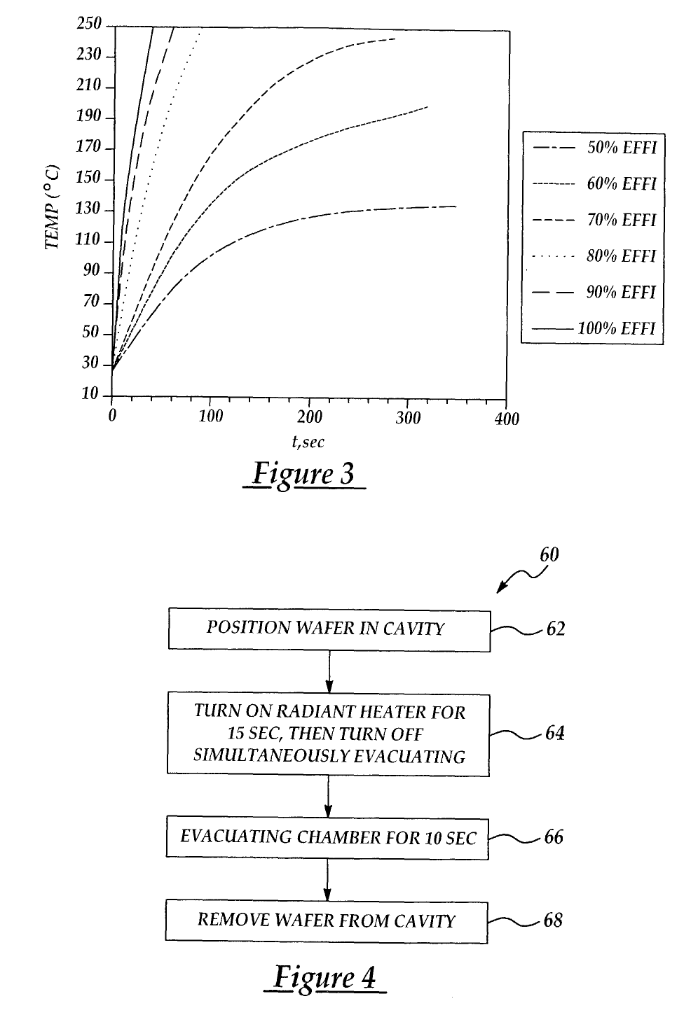

The effect of heating by a radiant heating device on a wafer surface is shown in FIG. 3. The dependency of the wafer surface temperature is plotted against the heating time in seconds, at six different levels of lamp efficiency. It is seen that at 100% efficiency, the temperature of the wafer surface exceeds 150° C. in a very short period of time, i.e. in about 10 sec. While at 50% lamp efficiency, an excessive length of time, i.e., about 200 sec. is required for the wafer temperature to reach 130° C. It is therefore recommended that a heating lamp that is at least 80% efficient should be utilized in order to rapidly heat the wafer surface to the desired temperature, i.e., above 100° C. within about 20 sec.

The present invention further discloses a method for cooling a wafer in a cool-down chamber without particulate contamination problems. The method is shown in a process flow chart 60 in FIG. 4.

As shown in FIG. 4, the cooling process can be started by first positioning a wafer in the cavity of the cool-down chamber, shown as step 62. In the next step of the process, the radiant heater is turned on for a time period of 15 sec., and then turned off as shown in step 64. During the heating process by the radiant heater, the exhaust means is simultaneously turned on to evacuate the chamber cavity. During this time period, which may be suitably between about 5 sec. and about 30 sec., and preferably at about 15 sec., any residual etchant gas is evacuated away by the exhaust means and does not form condensation on the hot wafer surface. After the radiant heater is turned off, as shown in step 66, the chamber cavity is continuously evacuated, or pumped, for a time period between about 10 sec. and about 20 sec. to assure that all residual etchant gas is removed from the chamber cavity and simultaneously, to cool-down the wafer by the gaseous flow through the chamber cavity over the top surface of the wafer. In the final step, i.e. step 68, the cooled wafer is removed from the chamber cavity. It has been discovered that after termination of the heating step, the evacuation step for the gaseous content in the chamber cavity should continue until a temperature of the wafer decreases to not higher than 70° C.

The present invention apparatus and method for preventing etchant gas condensation on a wafer surface positioned in a wafer cool-down chamber have therefore been amply described in the above description and in the appended drawings of FIGS. 2-4.

While the present invention has been described in an illustrative manner, it should be understood that the terminology used is intended to be in a nature of words of description rather than of limitation.

Furthermore, while the present invention has been described in terms of a preferred embodiment, it is to be appreciated that those skilled in the art will readily apply these teachings to other possible variations of the inventions.

The embodiment of the invention in which an exclusive property or privilege is claimed are defined as follows.

What is claimed is:

1. A process chamber for cooling a wafer comprising:
a chamber enclosure of elongated shape having a front end, a back end, and a top plate, said front end being equipped with an opening for loading/unloading a wafer into/out of a cavity in said chamber enclosure, said back end being equipped with an exhaust opening, said top plate being equipped with an aperture;
a heating device mounted on said top plate for heating through said aperture a wafer positioned in said cavity; and
an exhaust device in fluid communication with said exhaust opening in said chamber enclosure for evacuating gaseous content in said cavity and for cooling said wafer.

2. A process chamber for cooling a wafer according to claim 1, wherein said heating device comprises a radiant heating means.

3. A process chamber for cooling a wafer according to claim 1, wherein said heating device comprises a heating lamp.

4. A process chamber for cooling a wafer according to claim 1, wherein said heating device comprises a quartz lamp.

5. A process chamber for cooling a wafer according to claim 1, wherein said heating device further comprises a plurality of heating lamps.

6. A process chamber for cooling a wafer according to claim 1, wherein said exhaust device comprises a factory exhaust line.

7. A process chamber for cooling a wafer according to claim 1, wherein said exhaust device being capable of exhausting gaseous content of said cavity at a flow rate between about 1 CFM and about 50 CFM.

8. A process chamber for cooling a wafer according to claim 1, wherein said cavity in said chamber enclosure further comprises a support plate equipped with slots for positioning a plurality of wafers.

9. A method for cooling a wafer in a cool-down chamber without particulate contamination comprising the steps of:
providing a chamber enclosure of elongated shape having a front end, a back end, and a top plate, said front end being equipped with an opening for loading/unloading a wafer into/out of a cavity in said chamber enclosure, said back end being equipped with an exhaust opening in fluid communication with an exhaust means, said top plate being equipped with an aperture and a heating means mounted on said aperture;
heating a wafer positioned in said cavity to a temperature of at least 100° C. for a time period of at least 5 sec.;
evacuating, simultaneously with said heating step, a gaseous content in said cavity; and
evacuating, after termination of said heating step, a gaseous content in said cavity for at least 5 sec.

10. A method for cooling a wafer in a cool-down chamber without particulate contamination according to claim 9 further comprising the step of mounting a radiant heating means on said aperture of said top plate of the chamber enclosure.

11. A method for cooling a wafer in a cool-down chamber without particulate contamination according to claim 9 further comprising the step of mounting a heating lamp on said aperture of said top plate of the chamber enclosure.

12. A method for cooling a wafer in a cool-down chamber without particulate contamination according to claim 9 further comprising the step of mounting a plurality of radiant heating means on said aperture of said top plate of the chamber enclosure.

13. A method for cooling a wafer in a cool-down chamber without particulate contamination according to claim 9 further comprising the step of heating said wafer positioned in said cavity for a time period between about 5 sec. and about 30 sec.

14. A method for cooling a wafer in a cool-down chamber without particulate contamination according to claim 9 further comprising the step of heating said wafer positioned in said cavity preferably for a time period between about 10 sec. and about 20 sec.

15. A method for cooling a wafer in a cool-down chamber without particulate contamination according to claim 9 further comprising the step of evacuating, simultaneous with and after termination of said heating step, a gaseous content in said cavity for a total time period between about 10 sec. and about 50 sec.

16. A method for cooling a wafer in a cool-down chamber without particulate contamination according to claim 9 further comprising the step of evacuating, simultaneous with and after termination of said heating step, a gaseous content in said cavity at a flow rate of at least 1 CFM.

17. A method for cooling a wafer in a cool-down chamber without particulate contamination according to claim 9 further comprising the step of heating said wafer positioned in said cavity to a temperature of at least 150° C. for a time period of at least 5 sec.

18. A method for cooling a wafer in a cool-down chamber without particulate contamination according to claim 9 further comprising the step of evacuating, after termination of said heating step, a gaseous content in said cavity until a temperature of said wafer drops to not higher than 70° C.
